(19) United States
(12) Patent Application Publication
(10) Pub. No.: US 2017/0211185 A1
(43) Pub. Date: Jul. 27, 2017

(54) CERAMIC SHOWERHEAD WITH EMBEDDED CONDUCTIVE LAYERS

(71) Applicant: Applied Materials, Inc., Santa Clara, CA (US)

(72) Inventors: Dale R. DU BOIS, Los Gatos, CA (US); Karthik JANAKIRAMAN, San Jose, CA (US)

(21) Appl. No.: 15/367,828

(22) Filed: Dec. 2, 2016

Related U.S. Application Data
(60) Provisional application No. 62/281,995, filed on Jan. 22, 2016.

(51) Int. Cl. C23C 16/455

(52) U.S. Cl. CPC C23C 16/45565

(57) ABSTRACT

A method and apparatus for a showerhead is provided. In one embodiment, a showerhead for a semiconductor processing chamber is disclosed. The showerhead includes a body comprising a plurality of plates made of a dieletric material and having a plurality of holes formed therethrough, and a first conductive layer and a second conductive layer disposed in between the plates at different locations in the body.

### BACKGROUND

Field

Embodiments of the disclosure generally relate to a semiconductor processing chamber and, more specifically, heated support pedestal for a semiconductor processing chamber.

Description of the Related Art

Semiconductor processing involves a number of different chemical and physical processes whereby minute integrated circuits are created on a substrate. Layers of materials which make up the integrated circuit are created by chemical vapor deposition, physical vapor deposition, epitaxial growth, and the like. Some of the layers of material are patterned using photoresist masks and wet or dry etching techniques. The substrate utilized to form integrated circuits may be silicon, gallium arsenide, indium phosphide, glass, or other appropriate material.

In the manufacture of integrated circuits, plasma processes are often used for deposition or etching of various material layers. Plasma processing offers many advantages over thermal processing. For example, plasma enhanced chemical vapor deposition (PECVD) allows deposition processes to be performed at lower temperatures and at higher deposition rates than achievable in analogous thermal processes. Thus, PECVD is advantageous for integrated circuit fabrication with stringent thermal budgets, such as for very large scale or ultra-large scale integrated circuit (VLSI or ULSI) device fabrication.

The processing chambers used in these processes typically include a gas distribution plate or showerhead disposed therein to disperse gases during processing. Some of these showerheads may function as an electrode in a plasma process and are typically formed from an electrically conductive material. Spacing between the showerhead and the substrate are tightly controlled in order to promote uniform plasma formation and uniform deposition on the substrate. The conventional showerheads are typically heated by external heating elements to temperatures of about 250 degrees Celsius up to about 300 degrees Celsius. However, the conventional showerheads may bend or deflect (i.e., “droop”) at these temperatures which results in undesirable effects, such as non-uniform deposition and/or non-uniform plasma formation.

Therefore, what is needed is a showerhead having a heater embedded in a material that resists deflection at operating temperatures.

### SUMMARY

A method and apparatus for a showerhead is provided. In one embodiment, a showerhead for a semiconductor processing chamber is provided. The showerhead includes a body comprising a plurality of plates made of a dieletric material and having a plurality of holes formed therethrough, and a first conductive layer and a second conductive layer disposed in between the plates at different locations in the body.

In another embodiment, a showerhead for a semiconductor processing chamber is provided. The showerhead includes a body comprising a first plate, a second plate and a third plate, each of the plates made of a dieletric material and having a plurality of holes formed therethrough, a first conductive layer disposed between the first and second plates, and a second conductive layer disposed between the second and third plates.

In another embodiment, a showerhead for a semiconductor processing chamber is provided. The showerhead includes a body comprising a plurality of plates made of a dieletric material and having a plurality of holes formed therethrough, and a first conductive layer and a second conductive layer disposed in between the plates at different locations in the body, wherein the first conductive layer comprises a heater and a radio frequency electrode.

### BRIEF DESCRIPTION OF THE DRAWINGS

So that the manner in which the above-recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a schematic cross sectional view of a portion of a plasma system.

FIG. 2 is an exploded view of a portion of the showerhead of FIG. 1.

FIG. 3 is a plan view of the showerhead along lines 3-3 of FIG. 2.

FIG. 4 is an enlarged plan view of a portion of the showerhead of FIG. 3.

FIG. 5 is a cross sectional view of a portion of another embodiment of a plasma system utilizing embodiments of the showerhead as described herein.

FIG. 6 is an exploded view of another embodiment of a showerhead that may be used in the plasma system of FIG. 1 or FIG. 5.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments of the present disclosure are illustratively described below in reference plasma chambers, such as plasma chambers used for deposition or etch processes.

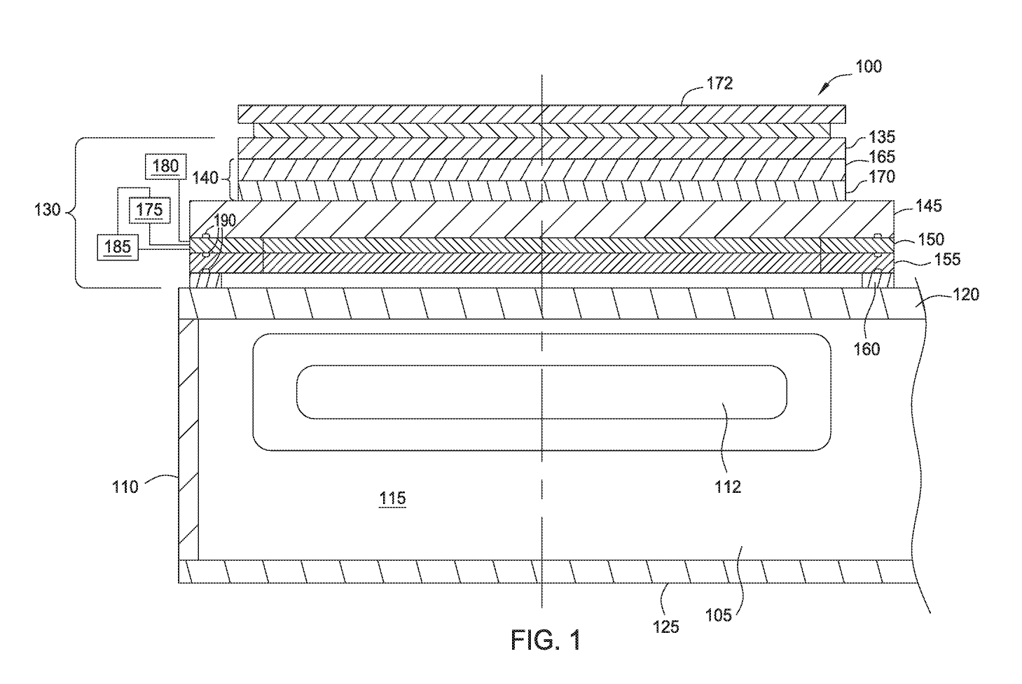

FIG. 1 is a schematic cross sectional view of a portion of a plasma system 100. The plasma system 100 generally comprises a processing chamber body 105 having a sidewall 110. A slit valve opening 112 is formed in the sidewall for transfer of a substrate (not shown) into and out of a processing volume 115. A lid plate 120 and a bottom 125, as well as the sidewall 110, bound the processing volume 115. A pedestal (not shown in FIG. 1) is positioned in the processing volume 115 for supporting the substrate therein.

A lid assembly 130 is disposed on the lid plate 120. The lid assembly 130 facilitates delivery of processing gas as well as electromagnetic energy delivery to the processing volume 115. The lid assembly 130 includes one or more of a gas box 135, a blocker plate assembly 140, a showerhead interface plate 145 and a showerhead 150. The lid assembly 130 may also include a first or upper radio frequency (RF) tuner plate 155 and a dielectric isolator ring 160. The blocker plate assembly 140 may include an upper or first blocker plate 165 and a lower or second blocker plate 170. A clamp plate 172 may be used to secure the lid assembly 130 to the chamber body 105.

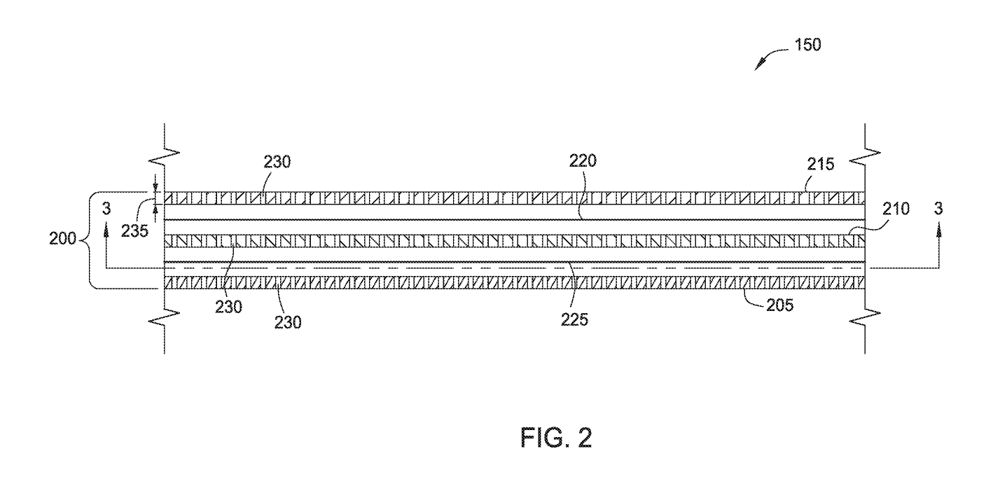

The showerhead 150 may be coupled to a power supply 175 for providing power to a heater (shown in FIG. 2) embedded in the showerhead 150. The showerhead 150 may also be coupled to a RF power source 180 for enabling a plasma in the processing volume 115. Additionally, the showerhead 150 may be coupled to a temperature control circuit 185 that facilitates closed-loop temperature control of the showerhead 150. Seals 190, such as elastomeric O-rings, may be provided at a perimeter of the showerhead 150 to seal the processing volume 115.

FIG. 2 is an exploded view of a portion of the showerhead 150 of FIG. 1. The showerhead 150 comprises a body 200 having a plurality of plates, such as a first plate 205, a second plate 210 and a third plate 215. Each of the plates 205, 210 and 215 may be made of one or more layers of a dielectric material or a ceramic material. In one embodiment, the plates 205, 210 and 215 comprise one or more layers of aluminum nitride (AlN). A conductive material layer, shown as a first conductive layer 220 and a second conductive layer 225, is provided between the plates 205, 210 and 215. The first conductive layer 220 may be thermocouple trace (i.e., a wire or wires) and the second conductive layer 225 may be a heater trace (i.e., a wire or wires). Dimensions of the wires of the second conductive layer 225 may be about 0.03 inches wide by about 0.007 inches thick in one embodiment.

Holes 230 are formed in each of the plates 205, 210 and 215 for dispersing gases through the body 200. The holes 230 may be formed mechanically (i.e., drilled) or with a laser when the plates 205, 210 and 215 are in a green state (prior to sintering). The first conductive layer 220 and the second conductive layer 225 are formed around the holes 230 to ensure electrical continuity. Each of the holes 230 may have a diameter of about 0.02 inches to about 0.032 inches, such as about 0.026 inches to about 0.03 inches. In some embodiments, the number of holes 230 is about 9,000 to about 10,000.

The plates 205, 210 and 215 shown in FIG. 2 are exploded and may be pressed together or fused to each other in a sintering process to embed the first conductive layer 220 and the second conductive layer 225 within the body 200. The first conductive layer 220 and the second conductive layer 225 may be a conductive metallic material such as copper, aluminum, tungsten, or combinations thereof. The first conductive layer 220 and the second conductive layer 225 may be deposited onto the plates 205, 210 and 215 by a silkscreen printing process, or other conventional deposition process. A thickness 235 of each of the plates 205, 210 and 215 may be about 1.5 microns (μm) to about 2 μm. In some embodiments, a thickness of the body 200 when the plates 205, 210 and 215 contact each other and/or are fused may be about 5.0 μm to about 6.5 μm.

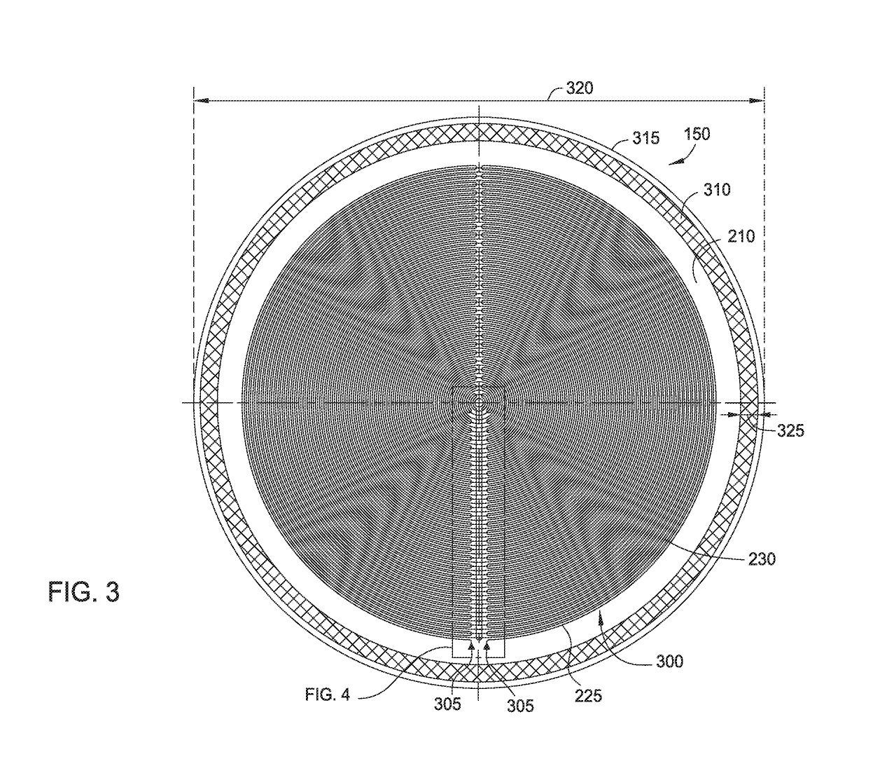

FIG. 3 is a plan view of the showerhead 150 along lines 3-3 of FIG. 2. The second conductive layer 225 is shown as a wire or wires on the plate 210. The second conductive layer 225 may define a heater 300 within the showerhead 150. Holes 230 are formed through the plate 210 and are concentric with holes on the plate 215 (not shown but below the plate 210. Terminals 305 may be provided to couple the heater 300 to the power supply 175 (shown in FIG. 1). Additionally, a seal region 310 may be disposed at a perimeter 315 of the showerhead 150. The seal region may be disposed on the plate 205 (shown in FIG. 2) and the heater 300 may be covered by the plate 205 shown in FIG. 2.

In some embodiments, a diameter 320 of the showerhead 150 (e.g., the outside dimension of the plates 205, 210 and 215) may be about 16.5 inches to about 17.5 inches. In some embodiments, a width 325 of the seal region 310 may be about 1 inch.

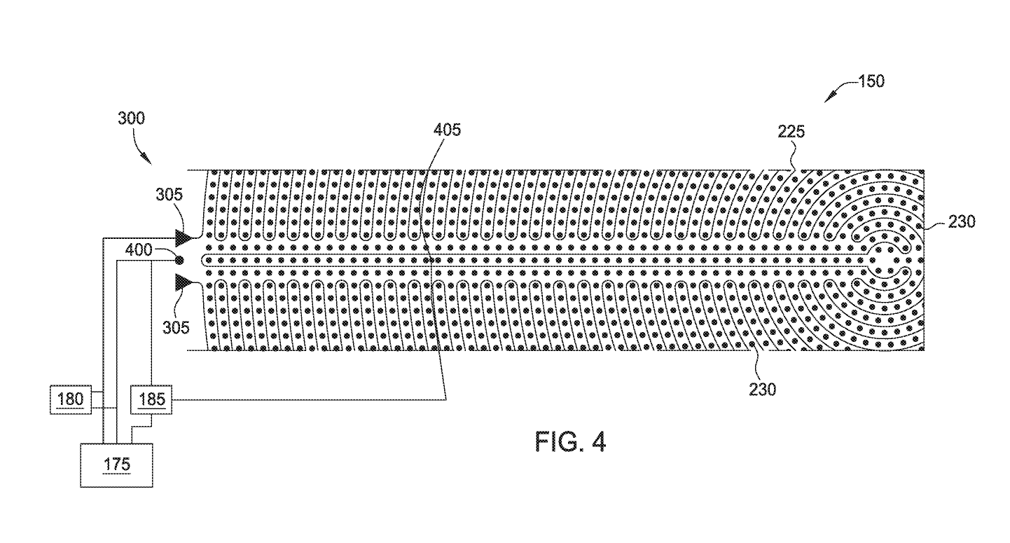

FIG. 4 is an enlarged plan view of a portion of the showerhead 150 of FIG. 3. The holes 230 and the second conductive layer 225 are more clearly shown in this view. The terminals are shown coupled to the power supply 175 and the heater 300 is coupled to the RF power source 180. Additionally, one or more resistive temperature devices 400 and 405 are shown on the showerhead 150. The resistive temperature devices 400 and 405 may be thermal sensors or thermocouples that are in electrical communication with the first conductive layer 220 shown in FIG. 2. The resistive temperature devices 400 and 405 may be coupled to the temperature control circuit 185 via the first conductive layer 220 in order to control temperature of the heater 300. The resistive temperature device 400 may be an over-temperature sensor while the resistive temperature device 405 may be a control sensor.

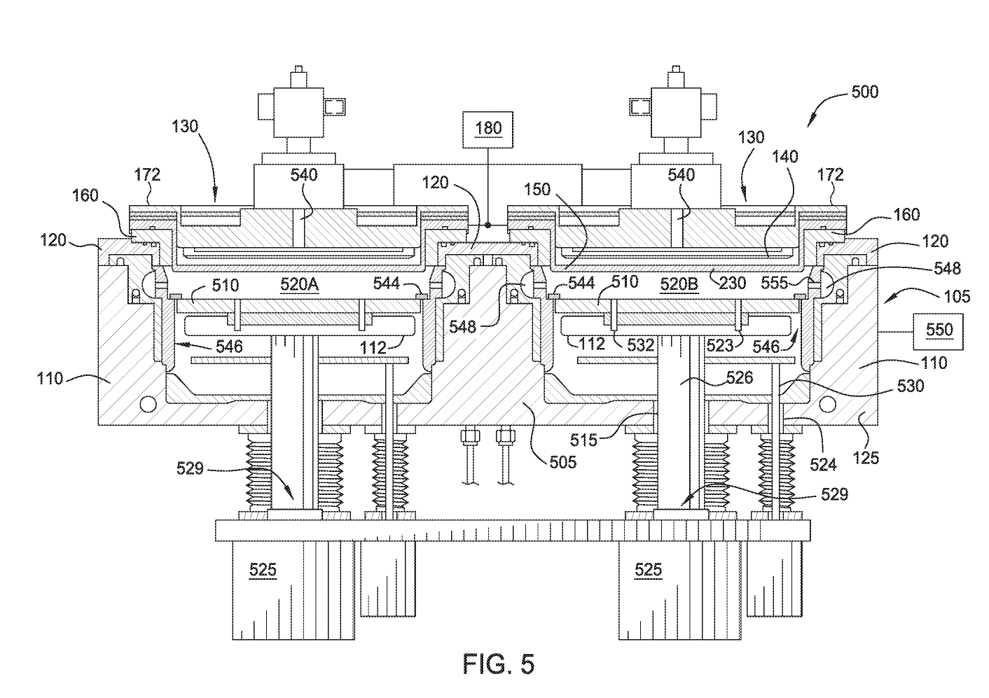

FIG. 5 is a cross sectional view of a portion of another embodiment of a plasma system 500. The plasma system 500 generally comprises a processing chamber body 105 having a sidewall 110, a bottom 125, and an interior sidewall 505 defining a pair of processing regions 520A and 520B. Each of the processing regions 520A-B is similarly configured, and for the sake of brevity, only components in the processing region 520B will be described.

A pedestal 510 is disposed in the processing region 520B through a passage 515 formed in the bottom wall 516 in the system 500. The pedestal 510 is adapted to support a substrate (not shown) on the upper surface thereof. The pedestal 510 may include heating elements, for example resistive elements, to heat and control the substrate temperature in a desired process temperature. Alternatively, the pedestal 510 may be heated by a remote heating element, such as a lamp assembly.

The pedestal 510 is coupled by a stem 526 to a power outlet or power box 525, which may include a drive system that controls the elevation and movement of the pedestal 510 within the processing region 520B. The stem 526 also contains electrical power interfaces to provide electrical power to the pedestal 510. The power box 525 also includes interfaces for electrical power and temperature indicators, such as a thermocouple interface. The stem 526 also includes a base assembly 529 adapted to detachably couple to the power box 525. A circumferential ring 535 is shown above the power box 525. In one embodiment, the circumferential ring 535 is a shoulder adapted as a mechanical stop or land configured to provide a mechanical interface between the base assembly 529 and the upper surface of the power box 525.

A rod 530 is disposed through a passage 524 formed in the bottom 125 and is utilized to activate substrate lift pins 532 disposed through the pedestal 510. The substrate lift pins 532 selectively space the substrate from the pedestal to facilitate exchange of the substrate with a robot (not shown) utilized for transferring the substrate into and out of the processing region 520B through a slit valve opening 112.

A lid plate 120 is coupled to a top portion of the chamber body 105. The lid plate 120 accommodates a lid assembly 130 as described in FIG. 1. The lid assembly 130 includes a gas inlet passage 540 which delivers reactant and cleaning gases through a blocker plate assembly 140 and a showerhead 150, as described herein, into the processing region 520B. A RF source 180 is coupled to the showerhead 150 as described herein. The RF source 180 powers the showerhead 150 to facilitate generation of a plasma between the showerhead 150 and the heated pedestal 510. In one embodiment, the RF source 180 may be a high frequency radio frequency (HFRF) power source, such as a 13.56 MHz RF generator. In another embodiment, RF source 180 may include a HFRF power source and a low frequency radio frequency (LFRF) power source, such as a 300 kHz RF generator. The dielectric isolator ring 160 is disposed between the lid plate 120 and the lid assembly 130 to prevent conducting RF power to the lid plate 120. A shadow ring 544 may be disposed on the periphery of the pedestal 510 that engages the substrate at a desired elevation of the pedestal 510.

A chamber liner assembly 546 is disposed within the processing region 520B in very close proximity to the sidewalls 505, 110 of the chamber body 105 to prevent exposure of the sidewalls 505, 110 to the processing environment within the processing region 520B. The liner assembly 546 includes a circumferential pumping cavity 548 that is coupled to a pumping system 550 configured to exhaust gases and byproducts from the processing region 520B and control the pressure within the processing region 520B. A plurality of exhaust ports 555 may be formed on the chamber liner assembly 546. The exhaust ports 555 are configured to allow the flow of gases from the processing region 520B to the circumferential pumping cavity 548 in a manner that promotes processing within the system 500.

In one embodiment, the plasma system 500 is utilized in a plasma enhanced chemical vapor deposition (PECVD) system. Examples of PECVD systems that may be adapted to benefit from the disclosure include a PRODUCER® SE CVD system, a PRODUCER® GT™ CVD system or a DXZ® CVD system, all of which are commercially available from Applied Materials, Inc., Santa Clara, Calif. The Producer® SE CVD system (e.g., 200 mm or 300 mm) has two isolated processing regions that may be used to deposit thin films on substrates, such as conductive films, silanes, carbon-doped silicon oxides and other materials. Although the exemplary embodiment includes two processing regions, it is contemplated that the disclosure may be used to advantage in systems having a single processing region or more than two processing regions. It is also contemplated that the disclosure may be utilized to advantage in other plasma chambers, including etch chambers, ion implantation chambers, plasma treatment chambers, and stripping chambers, among others. It is further contemplated that the disclosure may be utilized to advantage in plasma processing chambers available from other manufacturers.

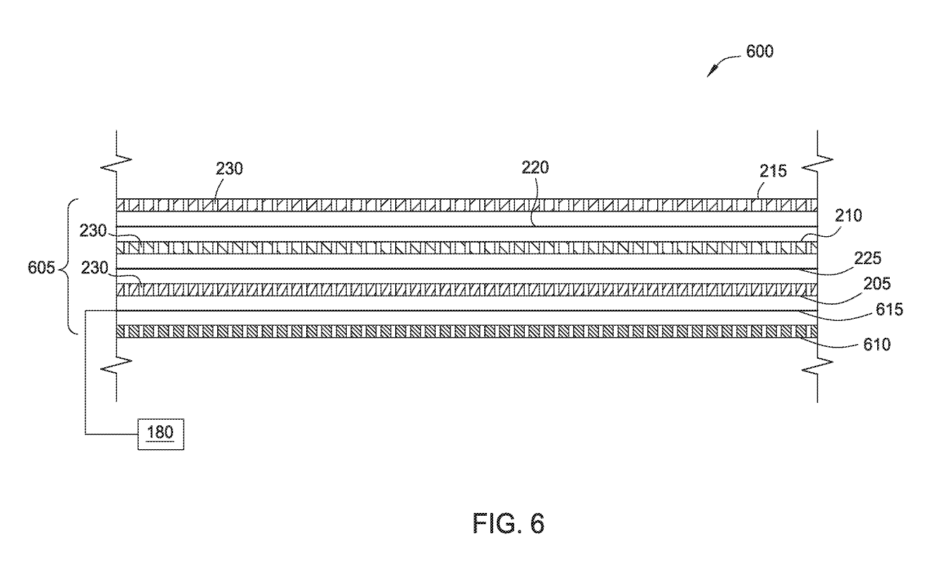

FIG. 6 is an exploded view of another embodiment of a showerhead 600 that may be used in the plasma system of FIG. 1 or FIG. 5. The showerhead 600 comprises a body 605 having a plurality of plates, such as the first plate 205, the second plate 210 and the third plate 215 having the first conductive layer 220 and the second conductive layer 225 disposed therebetween similar to the embodiment of FIG. 2. However, the showerhead 600 according to this embodiment includes a fourth plate 610 and a third conductive layer 615. The third conductive layer 615 may be a metallic material layer such as copper, aluminum, tungsten or another conductive metal. The plate 610 may be a dielectric or ceramic material similar to the plates 205, 210 and 215 of FIG. 2. The plates 205, 210, 215 and 610 may have the same thickness as the plates 205, 210 and 215 of FIG. 2. The third conductive layer 615 may function as a RF electrode while the first conductive layer 220 and the second conductive layer 225 may function as described in FIG. 2. The third conductive layer 615 may be coupled to the RF power source 180 as shown in order to facilitate plasma formation with a pedestal (not shown). The third conductive layer 615 may be a mesh or array of wires having dimensions about 0.03 inches wide by about 0.007 inches thick in one embodiment. The third conductive layer 615 may be deposited onto the plate 205 or plate 610 by a silkscreen printing process, or other conventional deposition process.

The plates 205, 210, 215 and 610 shown in FIG. 6 are exploded and may be pressed together or fused to each other in a sintering process to embed the first conductive layer 220, the second conductive layer 225 and the third conductive layer 615 within the body 605. In some embodiments, a thickness of the body 605 when the plates 205, 210, 215 and 610 contact each other and/or are fused may be about 6.0 μm to about 7.5 μm.

While the foregoing is directed to embodiments of the disclosure, other and further embodiments of the disclosure may be devised without departing from the basic scope thereof, and the scope thereof is determined by the claims that follow.

What is claimed is:

1. A showerhead for a semiconductor processing chamber, comprising:
a body comprising a plurality of fused plates made of a dieletric material, wherein each of the fused plates include a plurality of holes formed therethrough; and
a first conductive layer and a second conductive layer disposed between the fused plates at different locations in the body.

2. The showerhead of claim 1, wherein the first conductive layer comprises a heater.

3. The showerhead of claim 2, wherein the first conductive layer comprises an electrode.

4. The showerhead of claim 2, wherein the second conductive layer comprises a portion of a resistive temperature device.

5. The showerhead of claim 2, further comprising a third conductive layer disposed between the fused plates, the third conductive layer comprising a heater.

6. The showerhead of claim 1, wherein the first conductive layer comprises an electrode.

7. The showerhead of claim 6, wherein the second conductive layer comprises a portion of a resistive temperature device.

8. A showerhead for a semiconductor processing chamber, comprising:
a body comprising a first plate, a second plate and a third plate, each of the plates made of a dieletric material and having a plurality of holes formed therethrough;
a first conductive layer disposed between the first and second plates; and
a second conductive layer disposed between the second and third plates.

9. The showerhead of claim 8, wherein the first conductive layer comprises a heater.

10. The showerhead of claim 9, wherein the first conductive layer comprises an electrode.

11. The showerhead of claim 9, wherein the second conductive layer comprises a portion of a resistive temperature device.

12. The showerhead of claim 8, wherein the first conductive layer comprises an electrode.

13. The showerhead of claim 12, wherein the second conductive layer comprises a portion of a resistive temperature device.

14. A showerhead for a semiconductor processing chamber, comprising:
a body comprising a plurality of fused plates made of a dieletric material and having a plurality of holes formed therethrough; and
a first conductive layer and a second conductive layer disposed in between the fused plates at different locations in the body, wherein the first conductive layer comprises a heater or a radio frequency electrode.

15. The showerhead of claim 14, wherein the second conductive layer comprises a portion of a resistive temperature device.

16. The showerhead of claim 15, wherein the resistive temperature device comprises a first thermocouple.

17. The showerhead of claim 16, wherein the first thermocouple is positioned adjacent to a perimeter of the body.

18. The showerhead of claim 16, wherein the resistive temperature device comprises a second thermocouple.

19. The showerhead of claim 18, wherein the first thermocouple is positioned adjacent to a perimeter of the body.

20. The showerhead of claim 16, wherein the second thermocouple is positioned inward of the perimeter of the body.
